(19) United States
(12) Patent Application Publication
(10) Pub. No.: US 2011/0006382 A1
(43) Pub. Date: Jan. 13, 2011

(54) MEMS sensor, silicon microphone, and pressure sensor

(75) Inventor: Goro Nakatani, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/801,971

(22) Filed: Jul. 6, 2010

(30) Foreign Application Priority Data
Jul. 7, 2009 (JP) 2009-161038
Jul. 7, 2009 (JP) 2009-161039
May 26, 2010 (JP) 2010-120392

(51) Int. Cl. H01L 29/84

(52) U.S. Cl. 257/416; 257/419; 257/E29.324

(57) ABSTRACT

An MEMS sensor includes: a semiconductor substrate having an opening extending therethrough; a vibration diaphragm opposed to the opening in an opposing direction and capable of vibrating in the opposing direction; and a piezoelectric element or a strain gage provided in association with the vibration diaphragm.

### BACKGROUND OF THE INVENTION

1. Field of the Invention

The present invention relates to a sensor (MEMS sensor), a silicon microphone and a pressure sensor, which are produced by an MEMS (Micro-Electro-Mechanical Systems) technique.

2. Description of Related Art

One example of the MEMS sensor is a silicon microphone (Si microphone). Another example of the MEMS sensor is a pressure sensor which detects the pressure of a gas or a liquid.

Recently, silicon microphones have been increasingly employed instead of ECMs (Electret Condenser Microphones) mainly for mobile systems such as mobile phones.

For example, a silicon microphone disclosed in JP-A-2006-108491 includes a silicon substrate having an opening formed in a center portion thereof, a diaphragm (vibration diaphragm) disposed on a front surface of the silicon substrate in opposed relation to the opening, and a back plate opposed to and spaced a minute distance from the diaphragm. When a sound pressure (sound wave) is inputted to the silicon microphone, the diaphragm vibrates. When the diaphragm vibrates with a voltage applied between the diaphragm and the back plate, the capacitance of a capacitor defined by the diaphragm and the back plate is changed. A change in voltage between the diaphragm and the back plate due to the change in capacitance is outputted as a sound signal.

The prior art silicon microphone is produced by employing an SOI (Silicon-On-Insulator) substrate. The SOI substrate includes, for example, a silicon substrate, and a BOX (Buried Oxide) layer of SiO₂ (silicon oxide) and a silicon layer provided in this order on the silicon substrate. The silicon layer has a conductivity imparted by doping with a P-type or N-type impurity. The diaphragm is formed on the BOX layer by patterning the silicon layer. Thereafter, a sacrificial layer is formed on the diaphragm (patterned silicon layer), and then a back plate is formed on the sacrificial layer. In turn, openings are respectively formed in the silicon substrate and the BOX layer. Thus, the diaphragm is levitated above the silicon substrate. Further, the sacrificial layer between the diaphragm and the back plate is removed. Thus, the silicon microphone is completed.

As disclosed in United States Patent Application Publication No. US2005/0156241A1, a pressure sensor is produced by employing an SOI substrate and a glass substrate. First, a recess is formed in a silicon layer of the SOI substrate as having a depth such that a portion of the silicon layer is slightly left on the BOX layer. Then, a C-shaped groove is formed around the recess in the silicon layer as seen in plan. Thus, the portion of the silicon layer left in the bottom of the recess is processed into a diaphragm. Thereafter, portions of the silicon substrate and the BOX layer of the SIO substrate opposed to the diaphragm are removed. Then, a glass substrate having electrodes is bonded to the silicon substrate by an anodic bonding method. Thus, an air-tight reference pressure chamber is defined between the diaphragm and the glass substrate, and the pressure sensor is completed.

### SUMMARY OF THE INVENTION

However, the prior art MEMS sensors, i.e., the silicone microphone and the pressure sensor, are expensive, because the SOI substrates to be used for the production of the MEMS sensors are relatively costly.

It is an object of the present invention to provide an MEMS sensor which can be produced at lower costs.

The foregoing and other objects, features and effects of the present invention will become more apparent from the following detailed description of preferred embodiments with reference to the attached drawings.

### BRIEF DESCRIPTION OF THE DRAWINGS

FIG. 1 is a schematic plan view of a silicon microphone according to one embodiment of the present invention.

FIG. 2 is a schematic sectional view of the silicon microphone taken along a section line II-II in FIG. 1.

FIGS. 3A-3R are schematic sectional views for explaining a process for producing the silicon microphone shown in FIG. 2.

FIG. 4 is a schematic plan view of a pressure sensor according to another embodiment of the present invention.

FIG. 5 is a schematic sectional view of the pressure sensor taken along a section line V-V in FIG. 4.

FIGS. 6A-6N are schematic sectional views for explaining a process for producing the pressure sensor shown in FIG. 5.

### DETAILED DESCRIPTION OF PREFERRED EMBODIMENTS

An MEMS sensor according to one embodiment of the present invention includes a semiconductor substrate having an opening extending therethrough, a vibration diaphragm opposed to the opening in an opposing direction and capable of vibrating in the opposing direction, and a piezoelectric element or a strain gage provided in association with the vibration diaphragm.

The MEMS sensor can function, for example, as a silicon microphone. Where the piezoelectric element is provided on the vibration diaphragm, for example, a voltage occurring due to the piezoelectric effect is outputted as a sound signal from the piezoelectric element upon vibration of the vibration diaphragm. Hence, there is no need to provide a back plate which may otherwise be indispensable for providing a change in capacitance in the prior art silicon microphone. Without the provision of the back plate, the MEMS sensor serving as the silicon microphone according to the embodiment of the present invention has a correspondingly simplified construction and a correspondingly reduced thickness as compared with the prior art silicon microphone. Further, no photomask is required for forming the back plate, reducing the number of photomasks required for production of the silicon microphone.

Since the vibration diaphragm does not need to be electrically conductive, there is no need to use electrically conductive silicon, but SiO₂, SiN (silicon nitride), Poly-Si (polycrystalline silicon) or the like may be used as a material for the vibration diaphragm. This obviates the need for using the SOI substrate in the production of the silicon microphone. With the use of the silicon substrate, the inventive silicon microphone can be produced at lower costs than the prior art silicon microphone.

In the prior art silicon microphone, a change in capacitance occurs due to vibration of the diaphragm, and a change in voltage occurring due to the change in capacitance is outputted as a sound signal. Therefore, the prior art silicon microphone has a lower sensitivity. If it is desired to detect a minute sound wave (vibration), the sound signal should be significantly amplified. However, a noise component contained in the sound signal is also amplified by the amplification of the sound signal.

In contrast, where the silicon microphone is provided by the MEMS sensor according to the embodiment of the present invention and employs the piezoelectric element, for example, the vibration of the vibration diaphragm is converted directly to the voltage by the piezoelectric effect. Therefore, the voltage can be properly outputted in response to input of a minute sound wave. This eliminates the need for significantly amplifying the output voltage for detection of the minute sound wave, thereby reducing the noise contained in the sound signal.

Where the silicon microphone is provided by the MEMS sensor, it is preferred that the vibration diaphragm is supported by a portion of the semiconductor substrate around the opening, and the piezoelectric element is provided on the vibration diaphragm.

The vibration diaphragm preferably further has an air vent extending therethrough as communicating with the opening. Where the opening is closed by a closing member from a side opposite from the vibration diaphragm, the provision of the air vent prevents confinement of air in the opening (between the vibration diaphragm and the closing member), thereby permitting the vibration diaphragm to properly vibrate.

The MEMS sensor can also function, for example, as a pressure sensor. Where the strain gage is provided in the vibration diaphragm, for example, the vibration diaphragm may include a polysilicon layer which closes the opening of the semiconductor substrate from one of opposite sides of the semiconductor substrate. In this arrangement, the strain gage (polysilicon piezo-resistance) is formed of doped polysilicon provided by selectively doping the polysilicon layer with a conductivity-imparting impurity. When a pressure is applied to the polysilicon layer, the polysilicon layer is strain-deformed, and the electrical resistance of the strain gage is changed due to the strain deformation. Based on the change in electrical resistance, the level of the pressure applied to the polysilicon layer is detected.

In production of the pressure sensor, the polysilicon layer is first formed on the one side of the semiconductor substrate by a CVD (Chemical Vapor Deposition) method. Then, the polysilicon layer is selectively doped with the conductivity-imparting impurity for the formation of the strain gage. In turn, a portion of the semiconductor substrate opposed to the polysilicon layer is etched from the other side of the semiconductor substrate, whereby the opening is formed in the semiconductor substrate. Thus, the pressure sensor is produced.

Therefore, it is possible to use a less expensive substrate (e.g., a silicon substrate) as the semiconductor substrate for the production of the pressure sensor, obviating the need for using an SOI substrate that is much more expensive than the silicon substrate. Accordingly, the inventive pressure sensor can be produced at lower costs than the prior art pressure sensor.

In order to prevent the polysilicon layer from being etched during the formation of the opening in the semiconductor substrate, a film of a material having a proper etching selectivity with respect to the semiconductor substrate may be provided between the semiconductor substrate and the polysilicon layer. Where the semiconductor substrate is a silicon substrate, for example, a silicon oxide film may be used as the film.

The strain gage preferably has an impurity concentration of 1×10¹⁹/cm³ to 1×10²¹/cm³.

The strain gage preferably has a C-shape extending along the periphery of the opening inside the opening as seen in plan. With this arrangement, the electrical resistance of the strain gage can properly change with respect to deformation of the polysilicon layer in any of various directions, thereby improving the sensitivity of the pressure sensor.

Further, a semiconductor element may be formed in the MEMS sensor (either the silicon microphone or the pressure sensor) by utilizing the semiconductor substrate. In addition, an interconnection may be provided on the semiconductor substrate with the intervention of an interlevel insulating film, and connected to the semiconductor element via a contact plug or the like. Thus, the MEMS sensor can incorporate a circuit including the semiconductor element, the interconnection and the like. The semiconductor element may define a part of a signal processing circuit which processes a signal from an MEMS sensor portion (including the vibration diaphragm, and the piezoelectric element or the strain gage).

The semiconductor element and the interconnection are preferably provided around the vibration diaphragm in the semiconductor substrate. Thus, the MEMS sensor portion and the circuit (including the semiconductor element and the interconnection) can be integrated into a single chip.

Where the MEMS sensor is the pressure sensor, the semiconductor element may be, for example, a MISFET (Metal Insulator Semiconductor Field Effect Transistor). In this case, a gate electrode of the MISFET and the polysilicon layer can be formed at the same level in the same step. This simplifies a pressure sensor production process.

Embodiments of the present invention will hereinafter be described in detail with reference to the attached drawings.

More specifically, a silicon microphone and a pressure sensor will be described as specific examples of the MEMS sensor according to the embodiments of the present invention.

### (1) Silicon Microphone

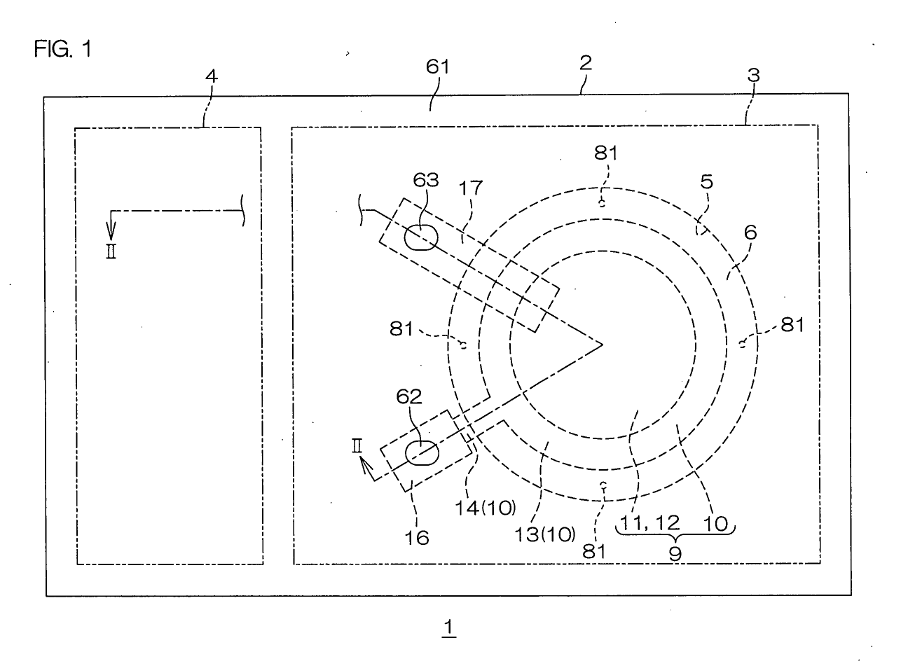

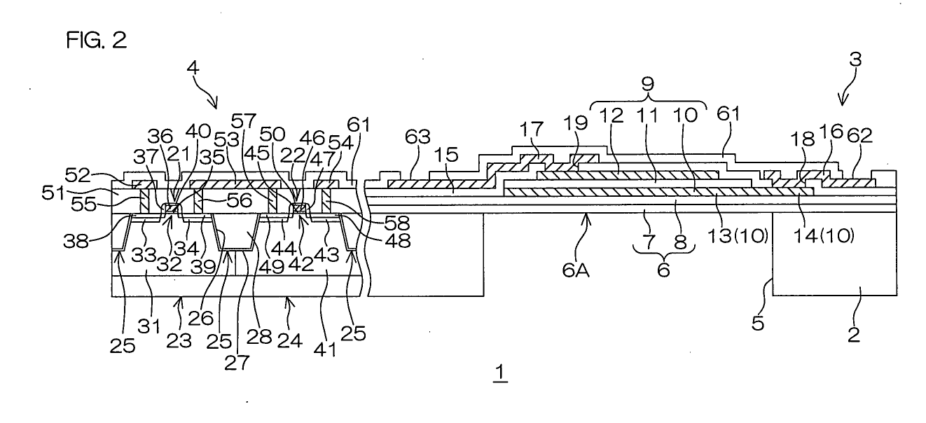

FIG. 1 is a schematic plan view of a silicon microphone according to one embodiment of the present invention. FIG. 2 is a schematic sectional view of the silicon microphone taken along a section line II-II in FIG. 1. In FIG. 2, only electrically conductive portions are hatched, and the other portions are not hatched.

The silicon microphone 1 includes a silicon substrate 2. A microphone formation region 3 and a circuit formation region 4 are defined in the silicon substrate 2.

The silicon substrate 2 has an opening 5 formed in the microphone formation region 3 as having a round plan shape and extending thicknesswise therethrough. The opening 5 has a diameter of, for example, 1 to 10 μm as measured on a front surface of the silicon substrate 2.

As shown in FIG. 2, a vibration diaphragm 6 is provided over the microphone formation region 3 on the front surface of the silicon substrate 2. The vibration diaphragm 6 has a double layer structure including an oxide film 7 of SiO₂ and a nitride film 8 of SiN stacked in this order from the side of the silicon substrate 2. The oxide film 7 has a thickness of, for example, 0.5 to 1.5 μm. The nitride film 8 has a thickness of, for example, 0.5 to 1.5 μm. Thus, the vibration diaphragm 6 is supported by a portion of the silicon substrate 2 around the opening 5, and is flexible enough to ensure that a portion (vibration portion) 6A thereof opposed to the opening 5 in an opposing direction can vibrate in the opposing direction.

A piezoelectric element 9 is provided on the vibration portion 6A of the vibration diaphragm 6. The piezoelectric element 9 includes a lower electrode 10, a piezoelectric member 11 provided on the lower electrode 10, and an upper electrode 12 provided on the piezoelectric member 11. In other words, the piezoelectric element 9 is configured such that the piezoelectric member 11 is held between the upper electrode 12 and the lower electrode 10 from upper and lower sides thereof.

The lower electrode 10 integrally includes a disk-shaped main portion 13 having a smaller diameter than the opening 5, and an extension portion 14 linearly extending from the periphery of the main portion 13 to the outside of the vibration portion 6A on the vibration diaphragm 6. The lower electrode 10 has a double layer structure including a Ti (titanium) layer and a Pt (platinum) layer stacked in this order from the side of the vibration diaphragm 6.

The piezoelectric member 11 has a disk shape having substantially the same diameter as the main portion 13 of the lower electrode 10 as seen in plan. The piezoelectric member 11 is formed of PZT (lead titanate zirconate Pb(Zr,Ti)O₃).

The upper electrode 12 has a disk shape having a smaller diameter than the piezoelectric member 11. The upper electrode 12 has a double layer structure including an IrO₂ (iridium oxide) layer and an Ir (iridium) layer stacked in this order from the side of the piezoelectric member 11.

The surfaces of the vibration diaphragm 6 and the piezoelectric element 9 are covered with an interlevel insulating film 15. The interlevel insulating film 15 is formed of SiO₂.

Interconnections 16, 17 are provided on the interlevel insulating film 15. The interconnections 16, 17 are each formed of a metal material containing Al (aluminum).

The interconnection 16 has opposite ends, one of which is disposed above a distal end of the extension portion 14 of the lower electrode 10. The interlevel insulating film 15 has a through-hole 18 formed therein between the one end of the interconnection 16 and the extension portion 14. The one end of the interconnection 16 is inserted in the through-hole 18 to be connected to the extension portion 14 in the through-hole 18. The other end of the interconnection 16 is spaced from the one end of the interconnection 16 away from the opening 5.

The interconnection 17 has opposite ends, one of which is disposed above the periphery of the upper electrode 12. The interlevel insulating film 15 further has a through-hole 19 formed therein between the one end of the interconnection 17 and the upper electrode 12. The one end of the interconnection 17 is inserted in the through-hole 19 to be connected to the upper electrode 12 in the through-hole 19. The other end of the interconnection 17 is spaced from the one end of the interconnection 17 away from the opening 5.

In the circuit formation region 4, an integrated circuit is provided which, for example, includes an N-channel MOSFET (Negative-Channel Metal Oxide Semiconductor Field Effect Transistor) 21 and a P-channel MOSFET (Positive-Channel Metal Oxide Semiconductor Field Effect Transistor) 22.

In the circuit formation region 4, an NMOS region 23 provided with the N-channel MOSFET 21 and a PMOS region 24 provided with the P-channel MOSFET 22 are isolated from their neighboring portions by a device isolation portion 25. The device isolation portion 25 is formed by forming a trench 26 recessed in the silicon substrate 2 to a smaller depth from the front surface of the silicon substrate 2 (e.g., a shallow trench having a depth of 0.2 to 0.5 μm), then forming a thermal oxide film 27 in an interior surface of the trench 26 by a thermal oxidation method, and depositing an insulator 28 (e.g., SiO₂) in the trench 26 by a CVD (Chemical Vapor Deposition) method.

A P-type well 31 is provided in the NMOS region 23. The P-type well 31 has a greater depth than the trench 26. The N-channel MOSFET 21 includes a source region 33 and a drain region 34 of an N-type provided on opposite sides of a channel region 32 in a surface portion of the P-type well 31. End portions of the source region 33 and the drain region 34 adjacent to the channel region 32 each have a smaller depth and a lower impurity concentration. That is, the N-channel MOSFET 21 has an LDD (Lightly Doped Drain) structure.

A gate insulating film 35 is provided on the channel region 32. The gate insulating film 35 is formed of SiO₂.

A gate electrode 36 is provided on the gate insulating film 35. The gate electrode 36 is formed of N-type Poly-Si (polycrystalline silicon).

A sidewall 37 is provided around the gate insulating film 35 and the gate electrode 36. The sidewall 37 is formed of SiN.

Silicide layers 38, 39, 40 are respectively provided on surfaces of the source region 33, the drain region 34 and the gate electrode 36.

An N-type well 41 is provided in the PMOS region 24. The N-type well 41 has a greater depth than the trench 26. The P-channel MOSFET 22 includes a source region 43 and a drain region 44 of a P-type provided on opposite sides of a channel region 42 in a surface portion of the N-type well 41. End portions of the source region 43 and the drain region 44 adjacent to the channel region 42 each have a smaller depth and a lower impurity concentration. That is, the P-channel MOSFET 22 has an LDD structure.

A gate insulating film 45 is provided on the channel region 42. The gate insulating film 45 is formed of SiO₂.

A gate electrode 46 is provided on the gate insulating film 45. The gate electrode 46 is formed of P-type Poly-Si.

A sidewall 47 is provided around the gate insulating film 45 and the gate electrode 46. The sidewall 47 is formed of SiN.

Silicide layers 48, 49, 50 are respectively provided on surfaces of the source region 43, the drain region 44 and the gate electrode 46.

In the circuit formation region 4, an interlevel insulating film 51 is provided on the front surface of the silicon substrate 2. The interlevel insulating film 51 is formed of SiO₂.

Interconnections 52, 53, 54 are provided on the interlevel insulating film 51. The interconnections 52, 53, 54 are formed of a metal material containing Al (aluminum).

The interconnection 52 is provided above the source region 33. A contact plug 55 extends through the interlevel insulating film 51 between the interconnection 52 and the source region 33 for electrical connection between the interconnection 52 and the source region 33. The contact plug 55 is formed of W (tungsten).

The interconnection 53 is provided above the drain region 34 and the drain region 44 as extending between the drain region 34 and the drain region 44. A contact plug 56 extends through the interlevel insulating film 51 between the interconnection 53 and the drain region 34 for electrical connection between the interconnection 53 and the drain region 34. Further, a contact plug 57 extends through the interlevel insulating film 51 between the interconnection 53 and the drain region 44 for electrical connection between the interconnection 53 and the drain region 44. The contact plugs 56, 57 are each formed of W.

The interconnection 54 is provided above the source region 43. A contact plug 58 extends through the interlevel insulating film 51 between the interconnection 54 and the source region 43 for electrical connection between the interconnection 54 and the source region 43. The contact plug 58 is formed of W.

A surface protecting film 61 is provided on an outermost surface of the silicon microphone 1. The surface protecting film 61 is formed of SiN. The interlevel insulating films 15, 51 and the interconnections 16, 17, 52, 53, 54 are covered with the surface protecting film 61. The surface protecting film 61 has openings through which the interconnections 16, 17 are partly exposed in the form of pads 62, 63.

When a sound wave (sound pressure) is inputted to the silicon microphone 1, the vibration diaphragm 6 is vibrated by the sound wave. The vibration of the vibration diaphragm 6 is transmitted to the piezoelectric element 9, and the vibration of the piezoelectric element 9 is converted to a voltage by the piezoelectric effect. Thus, the voltage is outputted from the piezoelectric element 9, and appears as a potential difference between the pads 62, 63. With the pads 62, 63 being electrically connected to the integrated circuit provided in the circuit formation region 4 via interconnections (not shown), the voltage outputted from the piezoelectric element 9 is inputted as a sound signal to the integrated circuit. An example of the integrated circuit is a signal processing circuit which performs a processing operation for amplification of the inputted sound signal or for removal of a noise component.

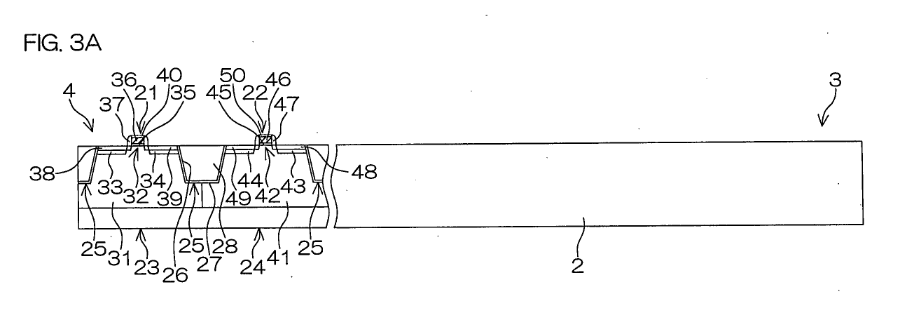

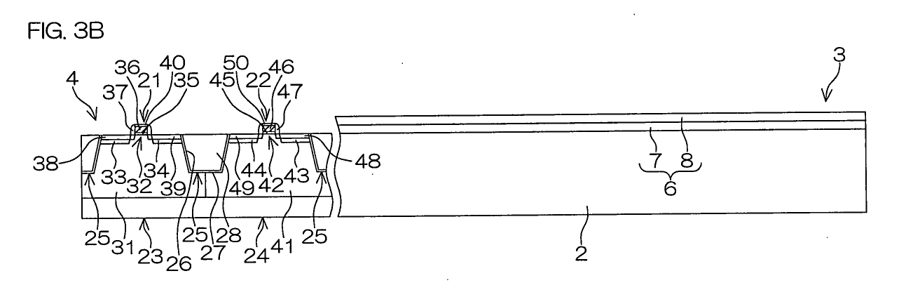

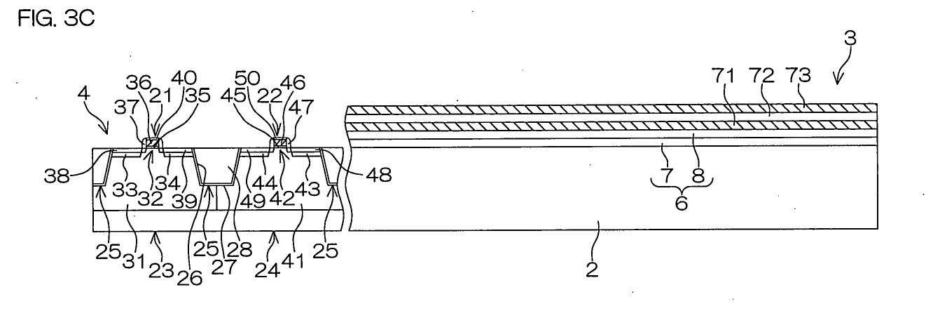

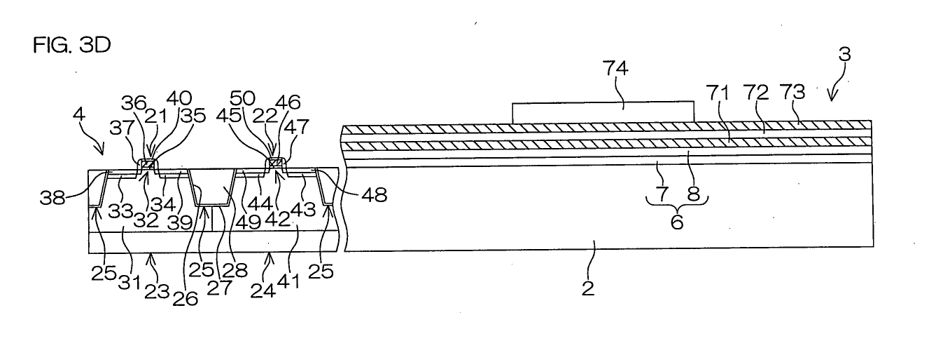

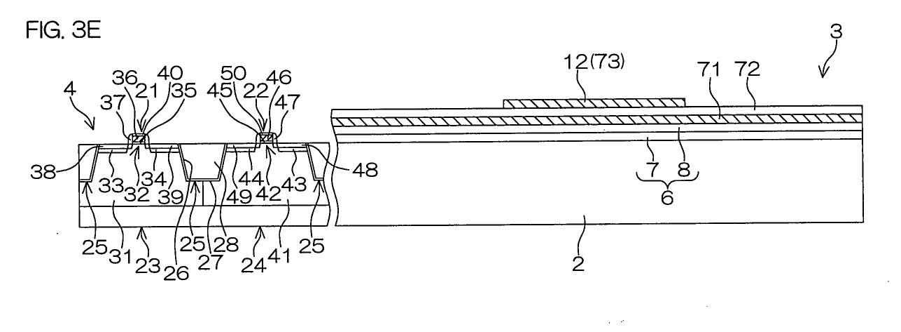

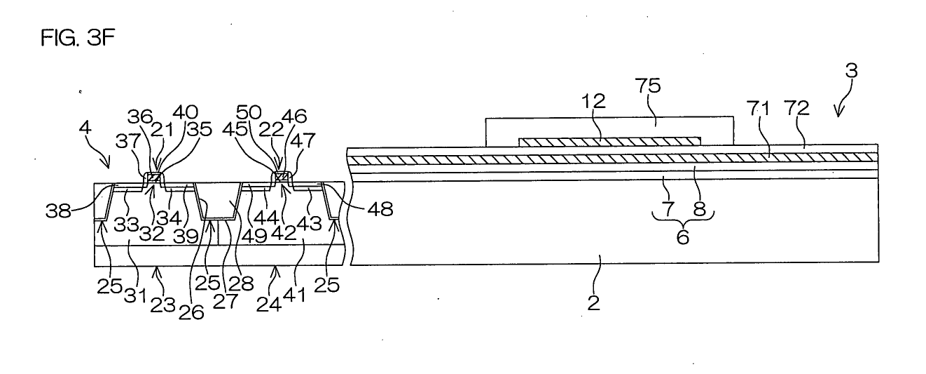

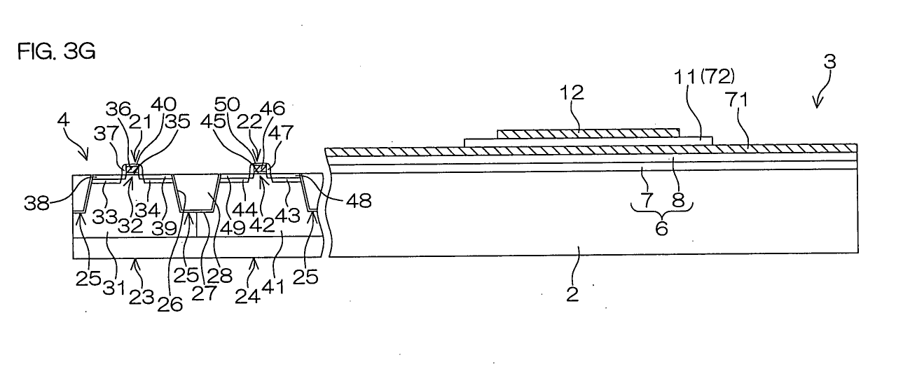

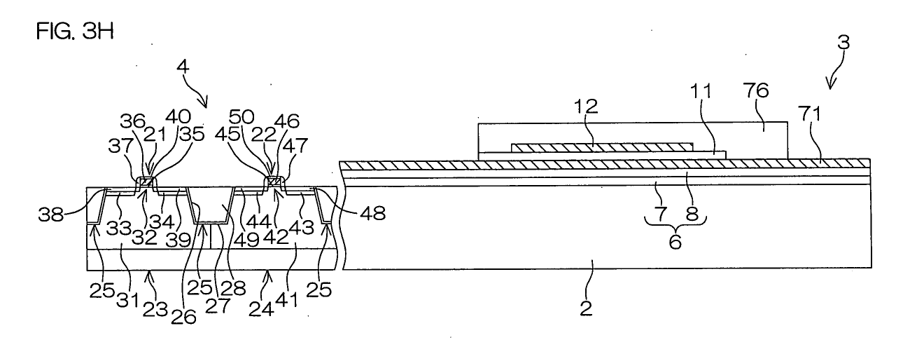

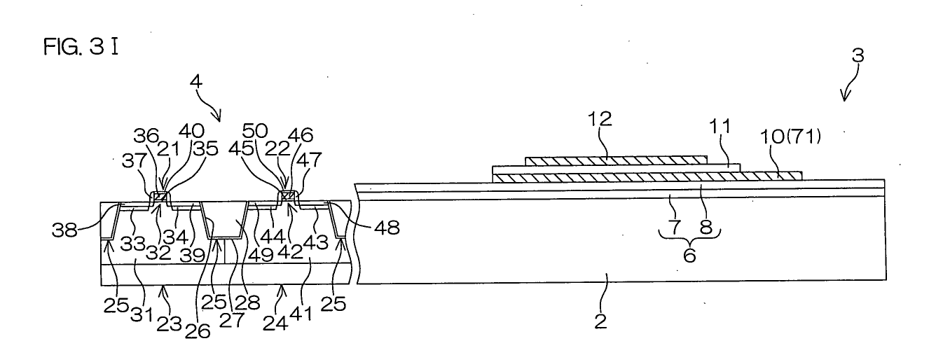

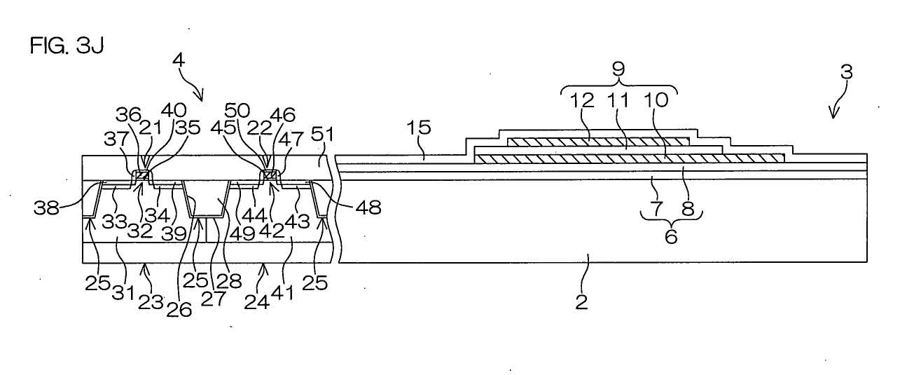

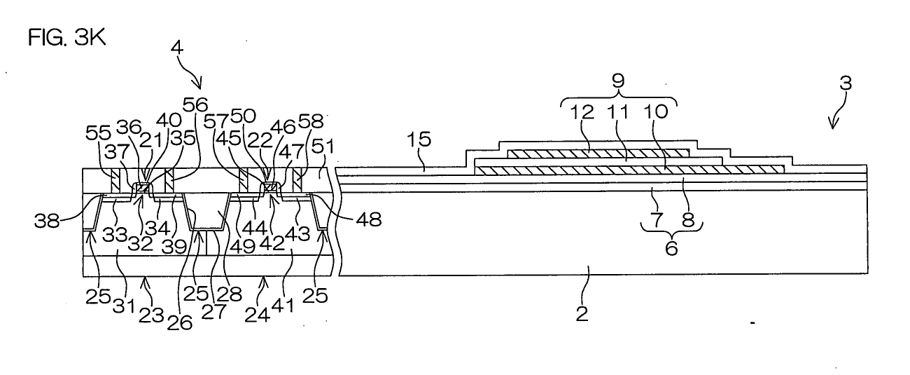

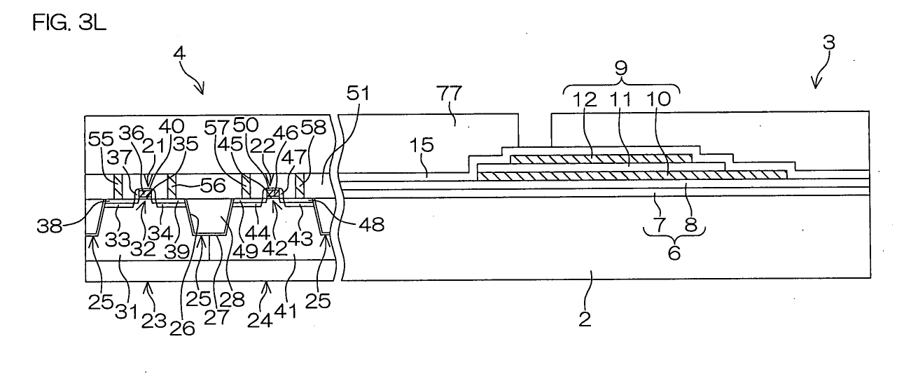

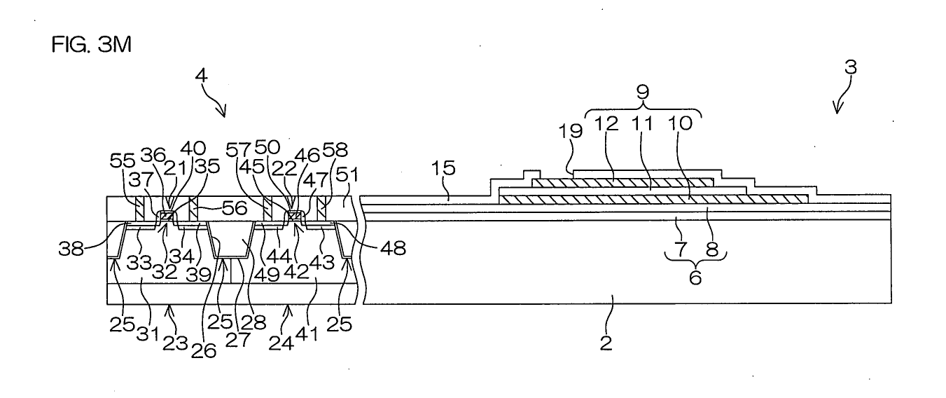

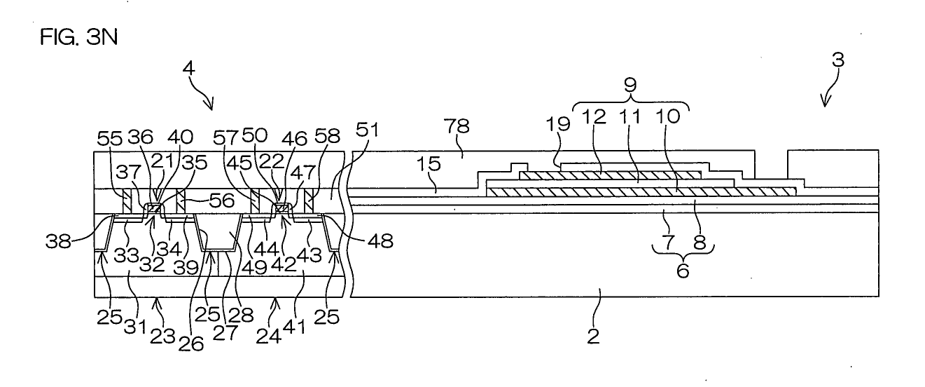

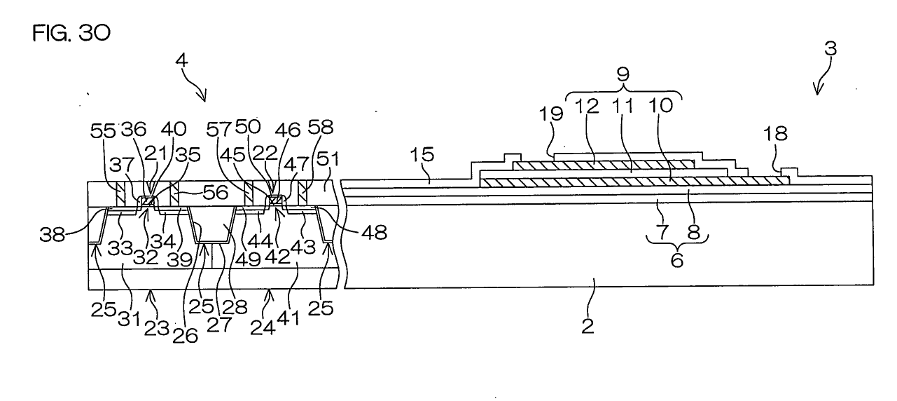

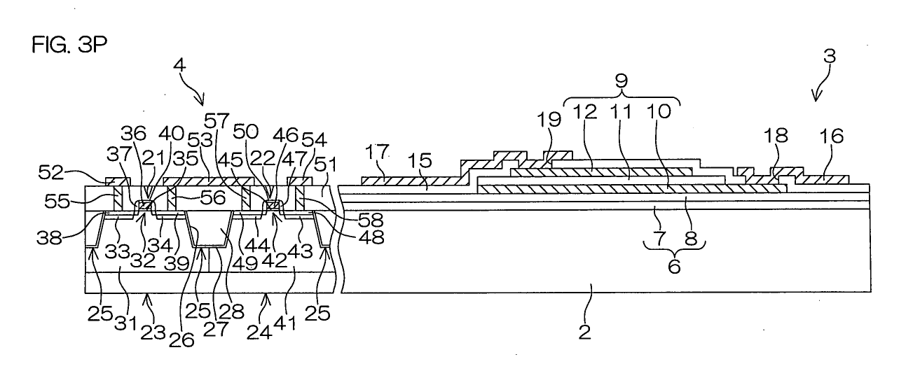

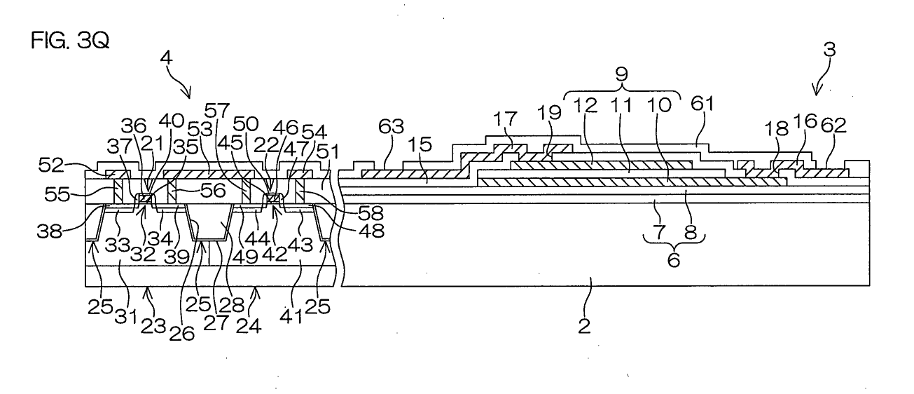

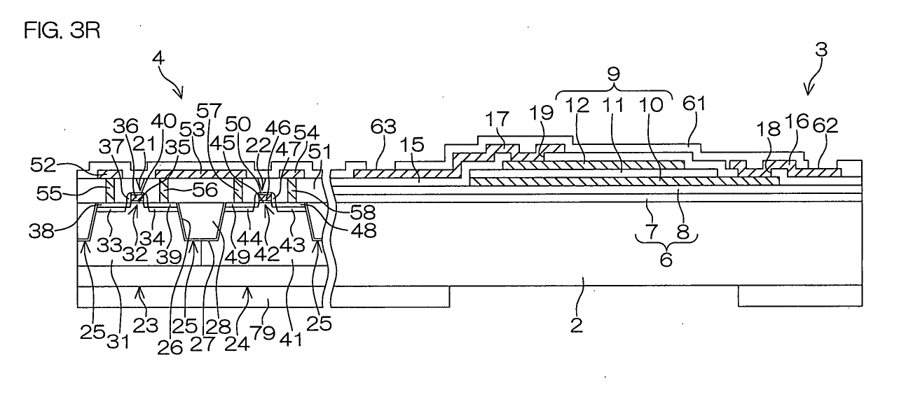

FIGS. 3A to 3R are schematic sectional views showing the steps of a silicon microphone production process in sequence.

In the process for producing the silicon microphone 1, a device isolation portion 25 is first formed in a surface portion of a silicon substrate 2 as shown in FIG. 3A. Thereafter, an N-channel MOSFET 21 and a P-channel MOSFET 22 are respectively formed in an NMOS region 23 and a PMOS region 24 by a known CMOS technique.

Then, as shown in FIG. 3B, an oxide film 7 is formed in a microphone formation region 3 on a front surface of the silicon substrate 2 by a thermal oxidation method or a CVD method. In turn, a nitride film 8 is formed on the oxide film 7 by a CVD method.

Thereafter, as shown in FIG. 3C, a film 71 having the same structure as a lower electrode 10 is formed over the nitride film 8 by a sputtering method. Further, a film 72 having the same structure as a piezoelectric member 11 is formed over the film 71 by a sputtering method or a sol-gel method. Further, a film 73 having the same structure as an upper electrode 12 is formed over the film 72 by a sputtering method.

Subsequently, as shown in FIG. 3D, a resist pattern 74 is formed on the film 73 as covering a portion of the film 73 later serving as the upper electrode 12 by photolithography.

Then, as shown in FIG. 3E, the film 73 is etched to be patterned by using the resist pattern 74 as a mask. Thus, the upper electrode 12 is formed. After the formation of the upper electrode 12, the resist pattern 74 is removed.

Thereafter, as shown in FIG. 3F, a resist pattern 75 is formed on the film 72 as covering a portion of the film 72 later serving as the piezoelectric member 11 by photolithography.

Then, as shown in FIG. 3G, the film 72 is etched to be patterned by using the resist pattern 75 as a mask. Thus, the piezoelectric member 11 is formed. After the formation of the piezoelectric member 11, the resist pattern 75 is removed.

Further, as shown in FIG. 3H, a resist pattern 76 is formed on the film 71 as covering a portion of the film 71 later serving as the lower electrode 10 by photolithography.

Then, as shown in FIG. 3I, the film 71 is etched to be patterned by using the resist pattern 76 as a mask. Thus, the lower electrode 10 is formed. After the formation of the lower electrode 10, the resist pattern 76 is removed.

In turn, as shown in FIG. 3J, interlevel insulating films 15, 51 are formed by a CVD method. The formation of the interlevel insulating film 51 is achieved, for example, by depositing SiO₂ in a circuit formation region 4 on the front surface of the silicon substrate 2 by CVD before the formation of the interlevel insulating film 15, and further depositing SiO₂ on a layer of the deposited SiO₂ during the formation of the interlevel insulating film 15.

After the formation of the interlevel insulating films 15, 51, through-holes are formed in the interlevel insulating film 51 in opposed relation to source regions 33, 43 and drain regions 34, 44 as extending thicknesswise through the interlevel insulating film 51 by photolithography and etching. Then, W is fed into the respective through-holes to completely fill the through-holes by a CVD method. Thus, contact plugs 55 to 58 are formed as shown in FIG. 3K.

Thereafter, as shown in FIG. 3L, a resist pattern 77 is formed on the interlevel insulating films 15, 51 by photolithography. The resist pattern 77 is configured such as to expose only a portion of the interlevel insulating film 15 to be formed with a through-hole 19 and cover the other portion of the interlevel insulating film 15 and the interlevel insulating film 51.

Then, as shown in FIG. 3M, the through-hole 19 is formed in the interlevel insulating film 15 by etching the interlevel insulating film 15 with the use of the resist pattern 77 as a mask. After the formation of the through-hole 19, the resist pattern 77 is removed.

In turn, as shown in FIG. 3N, a resist pattern 78 is formed on the interlevel insulating films 15, 51 by photolithography. The resist pattern 78 is configured such as to expose only a portion of the interlevel insulating film 15 to be formed with a through-hole 18 and cover the other portion of the interlevel insulating film 15 and the interlevel insulating film 51.

Then, as shown in FIG. 3O, the through-hole 18 is formed in the interlevel insulating film 15 by etching the interlevel insulating film 15 with the use of the resist pattern 78 as a mask. After the formation of the through-hole 18, the resist pattern 78 is removed.

After the removal of the resist pattern 78, an Al film is formed on the interlevel insulating films 15, 51. Then, the Al film is patterned by photolithography and etching, whereby interconnections 16, 17, 52, 53, 54 are formed as shown in FIG. 3P.

Thereafter, an SiN film is formed on the interlevel insulating films 15, 51 by a CVD method. Then, the SiN film is patterned by photolithography and etching, whereby a surface protecting film 61 is formed as having openings for exposing pads 62, 63 as shown in FIG. 3Q.

After the formation of the surface protecting film 61, as shown in FIG. 3R, a resist pattern 79 is formed on a rear surface of the silicon substrate 2 by photolithography. The resist pattern 79 is configured such as to expose a portion of the silicon substrate 2 to be formed with an opening 5 and cover the other portion of the silicon substrate 2. Then, the opening 5 is formed in the silicon substrate 2 by etching the silicon substrate 2 with the use of the resist pattern 79 as a mask. Thereafter, the resist pattern 79 is removed. Thus, the silicon microphone 1 shown in FIG. 2 is produced.

As described above, the voltage occurring due to the piezoelectric effect is outputted as the sound signal from the piezoelectric element 9 of the silicon microphone 1 upon the vibration of the vibration diaphragm 6. Hence, there is no need to provide the back plate, which may otherwise be indispensable for providing a change in capacitance in the prior art silicon microphone. Without the provision of the back plate, the silicon microphone 1 has a correspondingly simplified construction and a correspondingly reduced thickness as compared with the prior art silicon microphone. Further, no photomask is required for forming the back plate, reducing the number of photomasks required for the production of the silicon microphone 1.

Since the vibration diaphragm 6 does not need to be electrically conductive, SiO₂/SiN may be used for the silicon microphone 1 without the need for using electrically conductive silicon. This obviates the need for using an SOI substrate in the production of the silicon microphone 1. With the use of the silicon substrate 2, the silicon microphone 1 can be produced at lower costs than the prior art silicon microphone.

The structure of the vibration diaphragm 6 is not limited to the SiO₂/SiN double layer structure. For example, the vibration diaphragm 6 may have a single layer structure including a single layer formed of a material selected from the group consisting of SiO₂, SiN and Poly-Si, or a laminate structure including a plurality of layers respectively formed of materials selected from the group consisting of SiO₂, SiN and Poly-Si.

In the prior art silicon microphone, a change in capacitance occurs due to the vibration of the diaphragm, and a change in voltage occurring due to the change in capacitance is outputted as the sound signal. Therefore, the prior art silicon microphone has a lower sensitivity. If it is desired to detect a minute sound wave (vibration), the sound signal should be significantly amplified. However, a noise component contained in the sound signal is also amplified by the amplification of the sound signal.

In the silicon microphone 1, in contrast, the vibration of the vibration diaphragm 6 is converted directly to the voltage by the piezoelectric effect. Therefore, the voltage can be properly outputted in response to the minute sound wave. This eliminates the need for the amplification of the output voltage for detection of the minute sound wave, thereby reducing the noise contained in the sound signal.

The N-channel MOSFET 21, the P-channel MOSFET 22 and other semiconductor elements can be formed by utilizing the silicon substrate 2 which supports the vibration diaphragm 6. In the silicon microphone 1, the interconnections 52, 53, 54, which are provided on the silicon substrate 2 with the intervention of the interlevel insulating film 51, are connected to the N-channel MOSFET 21 and the P-channel MOSFET 22 via the contact plugs 55 to 58, whereby the integrated circuit is provided. The integrated circuit serves as a signal processing circuit which processes a signal from a silicon microphone portion (MEMS sensor portion) including the vibration diaphragm 6 and the piezoelectric element 9. The integrated circuit is preferably provided around the vibration diaphragm 6 in the silicon substrate 2. Thus, the integrated circuit and the silicon microphone portion can be integrated into a single chip.

While the silicon microphone 1 has thus been described by way of the embodiment, the present invention may be embodied in other ways.

For example, as indicated by a broken line in FIG. 1, the vibration diaphragm 6 preferably has air vents 81 extending therethrough and communicating with the opening 5. Where the opening 5 is closed by a closing member (not shown) from a side opposite from the vibration diaphragm 6, the provision of the air vents 81 prevents confinement of air in the opening 5 (between the vibration diaphragm 6 and the closing member), thereby permitting proper vibration of the vibration diaphragm 6.

The silicon microphone 1 employs the silicon substrate 2 as an example of the semiconductor substrate, but a substrate of a semiconductor material other than silicon, such as an SiC (silicon carbide) substrate, may be used instead of the silicon substrate 2.

Further, the silicon microphone may include a strain gage provided instead of the piezoelectric element 9 in the vibration diaphragm 6.

### (2) Pressure Sensor

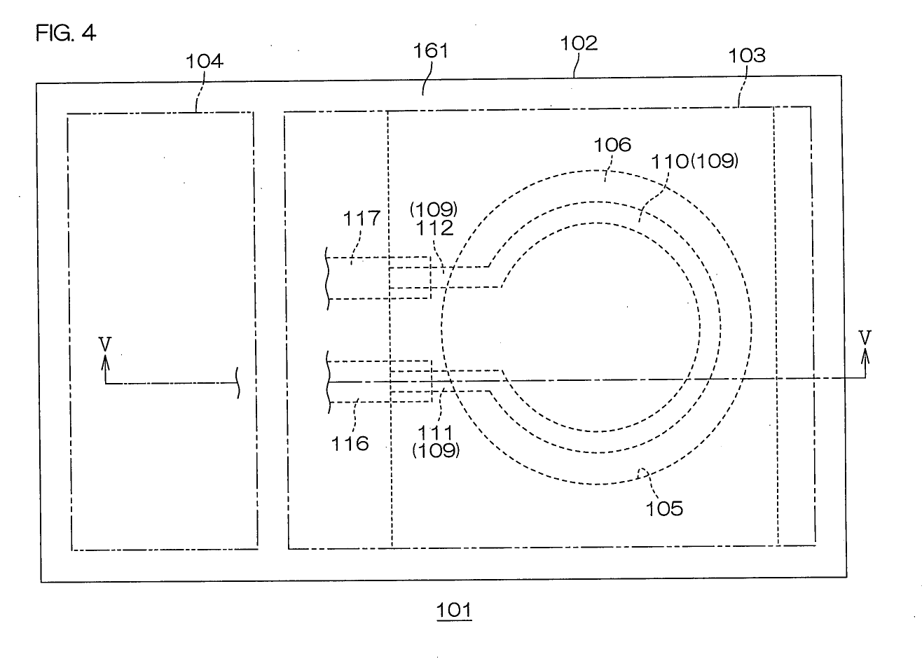

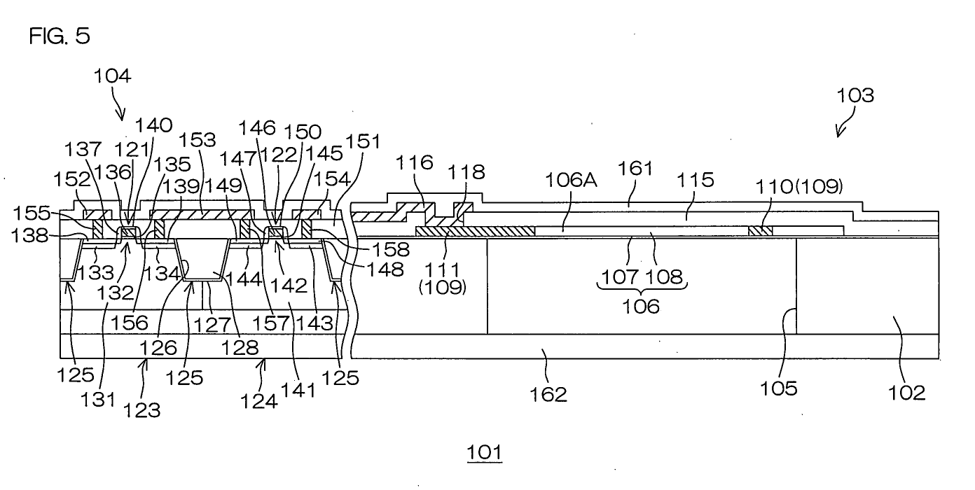

FIG. 4 is a schematic plan view of a pressure sensor according to another embodiment of the present invention. FIG. 5 is a schematic sectional view of the pressure sensor taken along a section line V-V in FIG. 4. In FIG. 5, only electrically conductive portions are hatched, and the other portions are not hatched.

The pressure sensor 101 includes a silicon substrate 102. A sensor region 103 and a circuit formation region 104 are defined in the silicon substrate 102.

The silicon substrate 102 has an opening 105 formed in the sensor region 103 thereof as having around plan shape and extending thicknesswise therethrough. The opening 105 has a diameter of, for example, 200 to 1000 μm as measured on a front surface of the silicon substrate 102.

As shown in FIG. 5, a diaphragm 106 is provided in the sensor region 103 on the front surface of the silicon substrate 102. The diaphragm 106 has a double layer structure including an oxide film 107 of SiO₂ and a polysilicon layer 108 of polysilicon stacked in this order from the side of the silicon substrate 102.

The oxide film 107 is provided over the sensor region 103. The oxide film 107 has a thickness of, for example, 0.3 to 1 μm.

The polysilicon layer 108 is opposed to the opening 105 and a portion of the silicon substrate 102 around the opening 105 with the intervention of the oxide film 107. The polysilicon layer 108 has a thickness of, for example, 0.1 to 0.5 μm.

The polysilicon layer 108 includes a strain gage 109 which is a so-called polysilicon piezo-resistance formed by selectively doping the polysilicon layer 108 with a conductivity-imparting impurity. The strain gage 109 has an impurity concentration of, for example, 1×10¹⁹ to 1×10²¹/cm³. As shown in FIG. 4, the strain gage 109 includes a main portion 110 having a C-shape extending along the periphery of the opening 105 inside the opening 105, and extension portions 111, 112 extending parallel to each other from opposite ends of the main portion 110.

A surface of the diaphragm 106 is covered with an interlevel insulating film 115. The interlevel insulating film 115 is formed of SiO₂.

Interconnections 116, 117 are provided on the interlevel insulating film 115. The interconnections 116, 117 are each formed of a metal material containing Al (aluminum).

One end of the interconnection 116 is disposed above an end of the extension portion 111. The interlevel insulating film 115 has a through-hole 118 formed therein between the one end of the interconnection 116 and the extension portion 111. The one end of the interconnection 116 is inserted in the through-hole 118 to be connected to the extension portion 111 in the through-hole 118. The interconnection 116 extends toward the circuit formation region 104.

One end of the interconnection 117 is disposed above the extension portion 112. The interlevel insulating film 115 further has a through-hole (not shown) formed therein between the one end of the interconnection 117 and the extension portion 112. The one end of the interconnection 117 is inserted in the through-hole to be connected to the extension portion 112 in the through-hole. The interconnection 117 extends toward the circuit formation region 104.

In the circuit formation region 104, an integrated circuit is provided which, for example, includes an N-channel MOSFET (Negative-Channel Metal Oxide Semiconductor Field Effect Transistor) 121 and a P-channel MOSFET (Positive-Channel Metal Oxide Semiconductor Field Effect Transistor) 122.

In the circuit formation region 104, an NMOS region 123 provided with the N-channel MOSFET 121 and a PMOS region 124 provided with the P-channel MOSFET 122 are isolated from their neighboring portions by a device isolation portion 125. The device isolation portion 125 is formed by forming a trench 126 recessed in the silicon substrate 102 to a smaller depth from the front surface of the silicon substrate 102 (e.g., a shallow trench having a depth of 0.2 to 0.5 μm), then forming a thermal oxide film 127 in an interior surface of the trench 126 by a thermal oxidation method, and depositing an insulator 128 (e.g., SiO₂) in the trench 126 by a CVD (Chemical Vapor Deposition) method.

A P-type well 131 is provided in the NMOS region 123. The P-type well 131 has a greater depth than the trench 126. The N-channel MOSFET 121 includes a source region 133 and a drain region 134 of an N-type provided on opposite sides of a channel region 132 in a surface portion of the P-type well 131. End portions of the source region 133 and the drain region 134 adjacent to the channel region 132 each have a smaller depth and a lower impurity concentration. That is, the N-channel MOSFET 121 has an LDD (Lightly Doped Drain) structure.

A gate insulating film 135 is provided on the channel region 132. The gate insulating film 135 is formed of SiO₂, and provided at the same level as the oxide film 107 of the diaphragm 106.

A gate electrode 136 is provided on the gate insulating film 135. The gate electrode 136 is formed of polysilicon doped with a conductivity-imparting impurity, and provided at the same level as the polysilicon layer 108 of the diaphragm 106. The gate electrode 136 has an impurity concentration of, for example, 1×10²⁰ to 1×10²¹/cm³.

A sidewall 137 is provided around the gate insulating film 135 and the gate electrode 136. The sidewall 137 is formed of SiN.

Silicide layers 138, 139, 140 are respectively provided on surfaces of the source region 133, the drain region 134 and the gate electrode 136.

An N-type well 141 is provided in the PMOS region 124. The N-type well 141 has a greater depth than the trench 126. The P-channel MOSFET 122 includes a source region 143 and a drain region 144 of a P-type provided on opposite sides of a channel region 142 in a surface portion of the N-type well 141. End portions of the source region 143 and the drain region 144 adjacent to the channel region 142 each have a smaller depth and a lower impurity concentration. That is, the P-channel MOSFET 122 has an LDD structure.

A gate insulating film 145 is provided on the channel region 142. The gate insulating film 145 is formed of SiO₂, and provided at the same level as the gate insulating film 135 and the oxide film 107 of the diaphragm 106.

A gate electrode 146 is provided on the gate insulating film 145. The gate electrode 146 is formed of polysilicon doped with a conductivity-imparting impurity, and provided at the same level as the gate electrode 136 and the polysilicon layer 108 of the diaphragm 106. The gate electrode 146 has an impurity concentration of, for example, 1×10²⁰ to 1×10²¹/cm³.

A sidewall 147 is provided around the gate insulating film 145 and the gate electrode 146. The sidewall 147 is formed of SiN.

Silicide layers 148, 149, 150 are respectively provided on surfaces of the source region 143, the drain region 144 and the gate electrode 146.

In the circuit formation region 104, an interlevel insulating film 151 is provided on the front surface of the silicon substrate 102. The interlevel insulating film 151 is formed of SiO₂, and provided at the same level as the interlevel insulating film 115.

Interconnections 152, 153, 154 are provided on the interlevel insulating film 151. The interconnections 152, 153, 154 are formed of a metal material containing Al (aluminum), and provided at the same level as the interconnections 116, 117.

The interconnection 152 is provided above the source region 133. A contact plug 155 extends through the interlevel insulating film 151 between the interconnection 152 and the source region 133 for electrical connection between the interconnection 152 and the source region 133. The contact plug 155 is formed of W (tungsten).

The interconnection 153 is provided above the drain region 134 and the drain region 144 as extending between the drain region 134 and the drain region 144. A contact plug 156 extends through the interlevel insulating film 151 between the interconnection 153 and the drain region 134 for electrical connection between the interconnection 153 and the drain region 134. A contact plug 157 extends through the interlevel insulating film 151 between the interconnection 153 and the drain region 144 for electrical connection between the interconnection 153 and the drain region 144. The contact plugs 156, 157 are each formed of W.

The interconnection 154 is provided above the source region 143. A contact plug 158 extends through the interlevel insulating film 151 between the interconnection 154 and the source region 143 for electrical connection between the interconnection 154 and the source region 143. The contact plug 158 is formed of W.

A surface protecting film 161 is provided on an outermost surface of the pressure sensor 101. The surface protecting film 161 is formed of SiN. The interlevel insulating films 115, 151 and the interconnections 116, 117, 152, 153, 154 are covered with the surface protecting film 161. The surface protecting film 161 has a thickness of, for example, 0.5 to 1.5 μm.

A glass plate 162 is bonded to a rear surface of the silicon substrate 102. Thus, a closed space is defined in the opening 105.

The diaphragm 106 is flexible enough to ensure that a portion 106A thereof opposed to the opening 105 of the silicon substrate 102 in an opposing direction can vibrate in the opposing direction. When a pressure is applied to the diaphragm 106, the diaphragm 106 is strain-deformed, and the electrical resistance of the strain gage 109 is changed due to the strain deformation of the diaphragm 106. A change in electrical resistance appears as a change in voltage between the interconnections 116 and 117. Based on the change in voltage, the level of the pressure applied to the diaphragm 106 is detected. With the interconnections 116, 117 being electrically connected to the integrated circuit provided in the circuit formation region 104, the voltage between the interconnections 116, 117 is inputted as a signal to the integrated circuit. An example of the integrated circuit is a signal processing circuit which performs a processing operation for amplification of the inputted signal or for removal of a noise component.

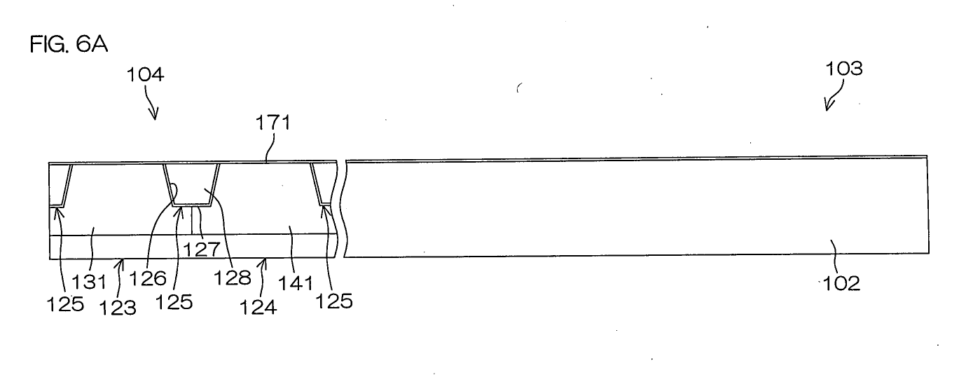

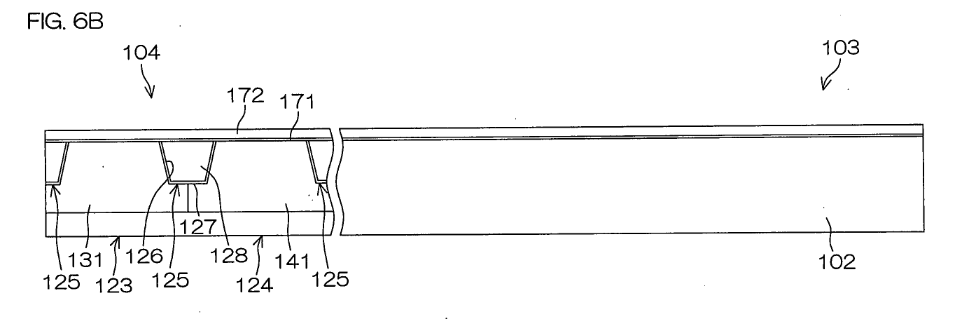

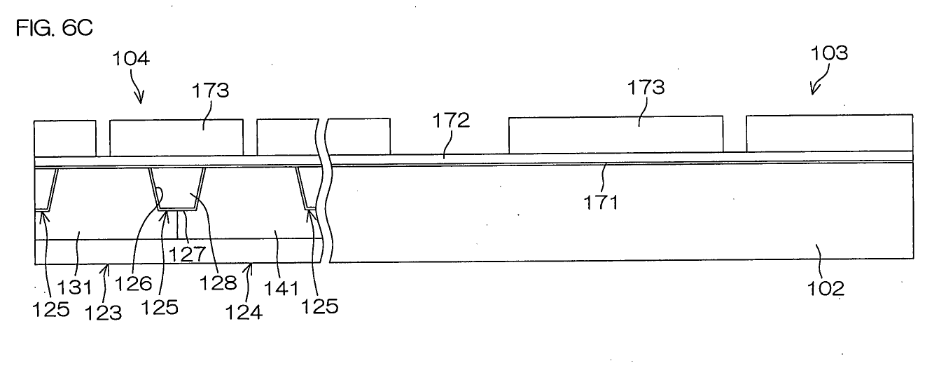

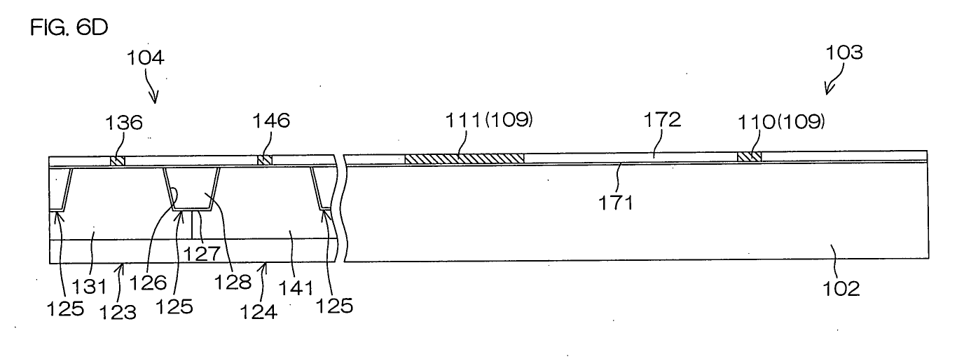

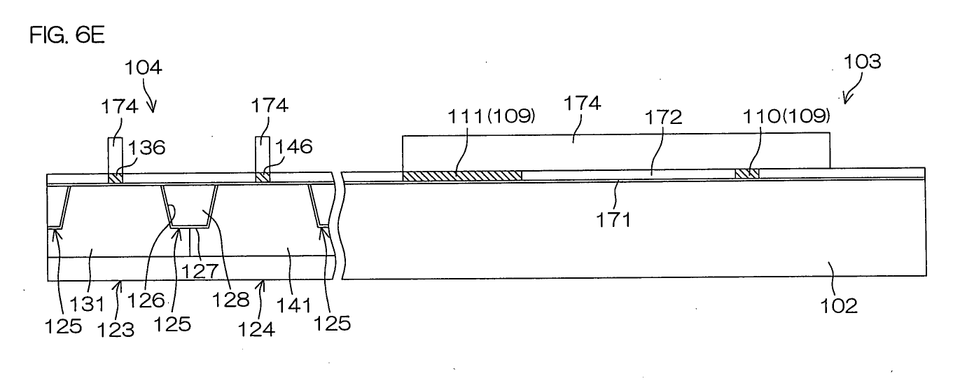

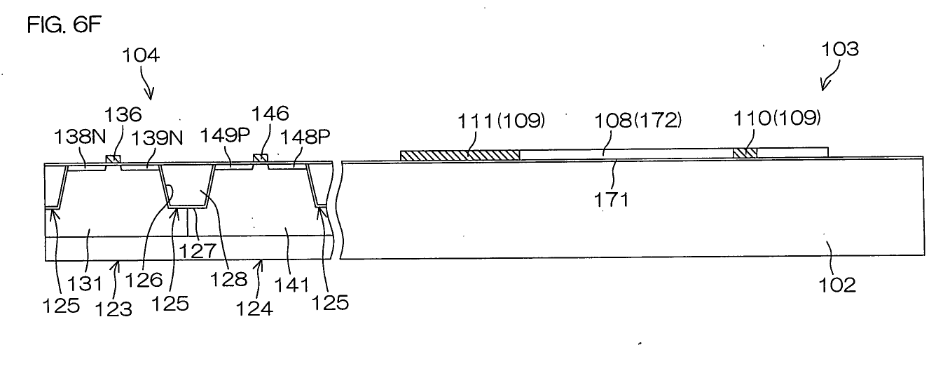

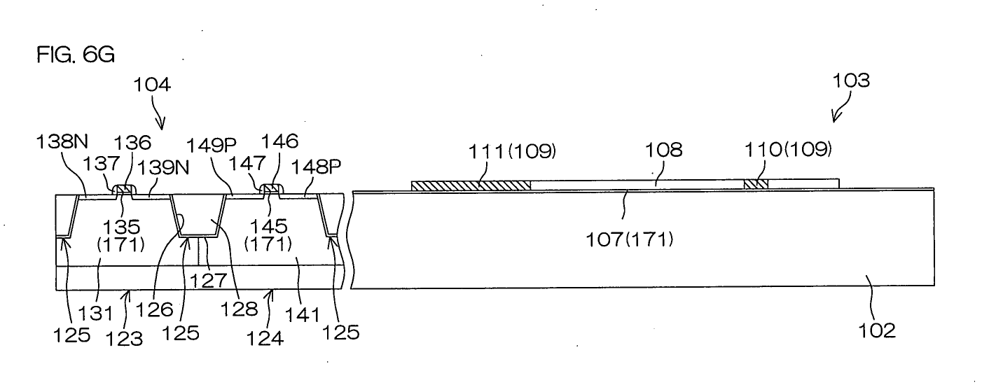

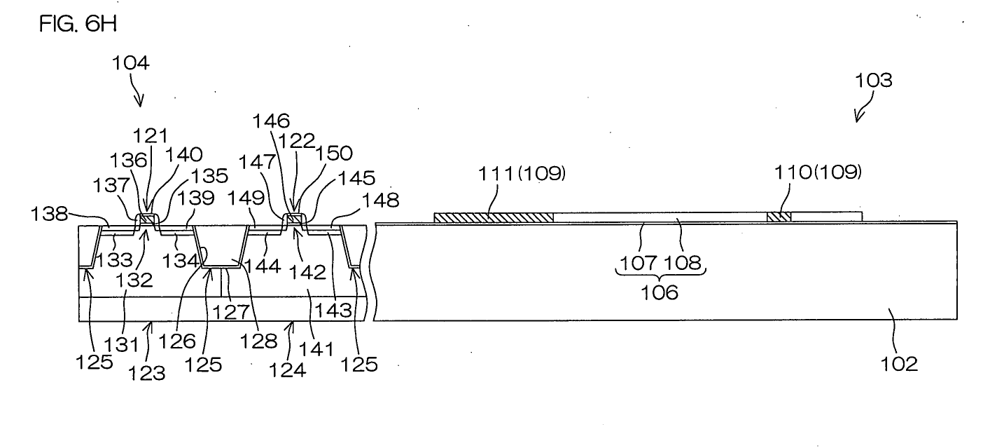

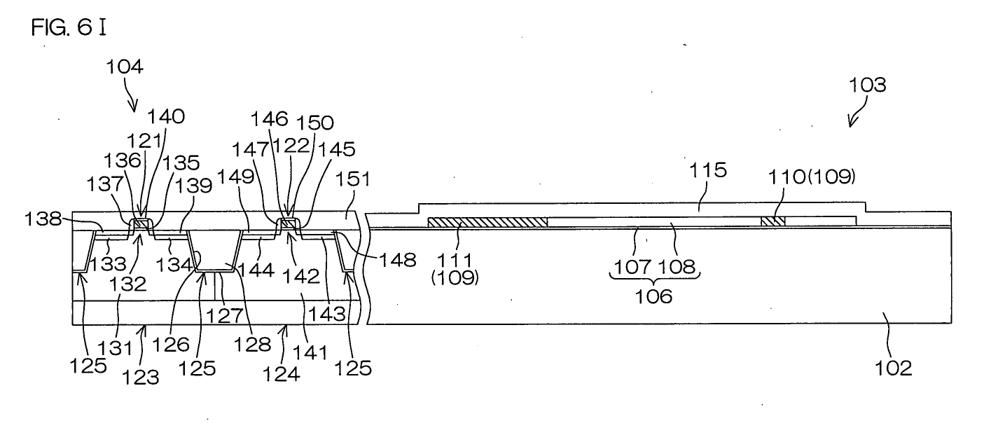

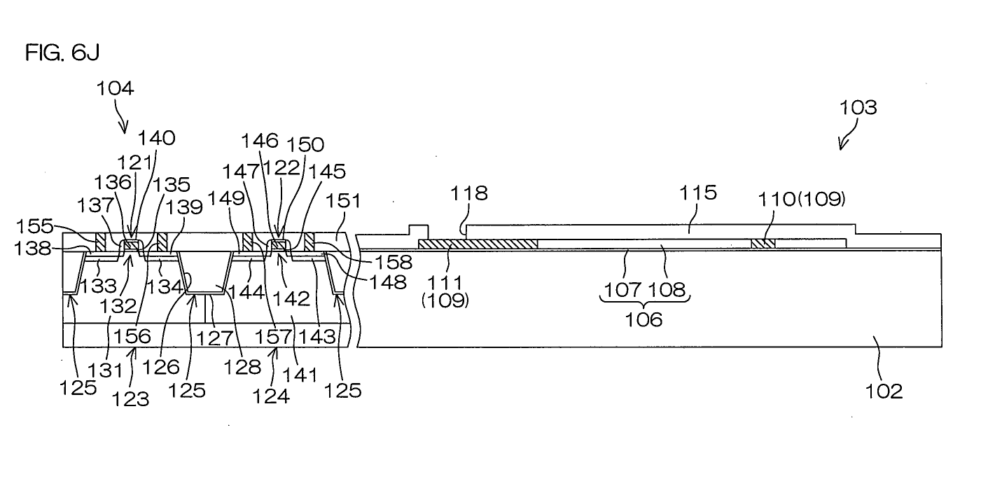

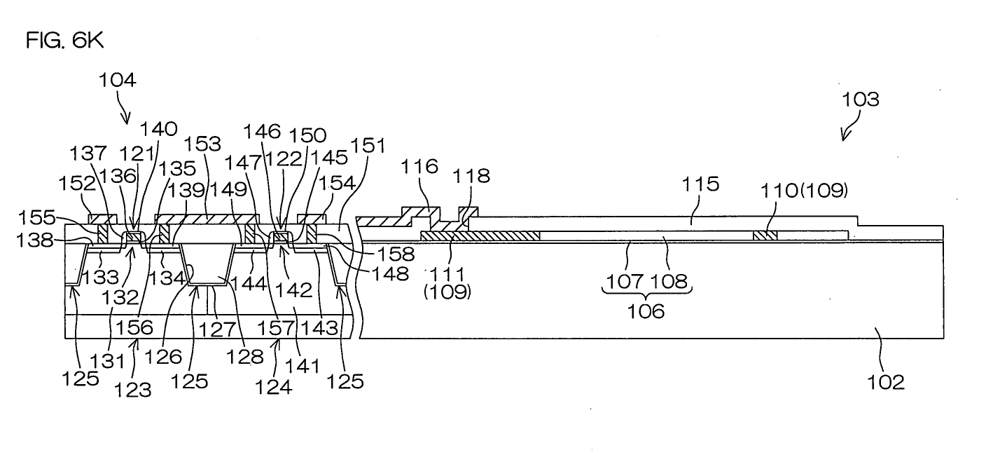

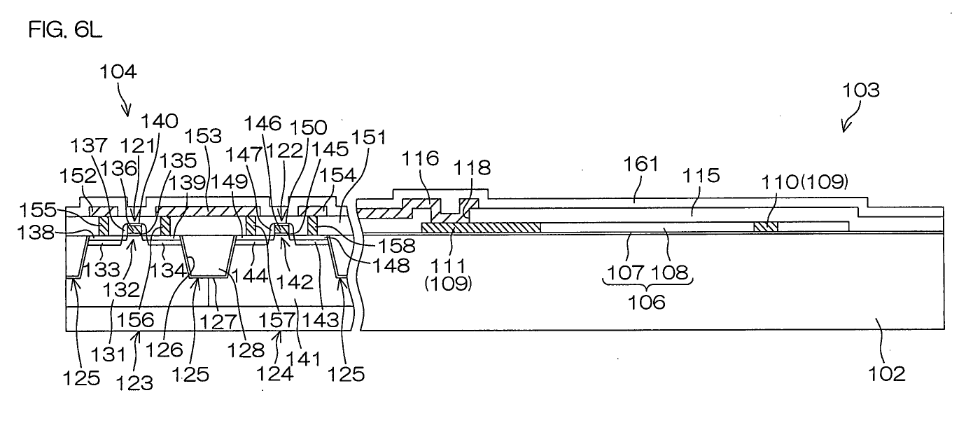

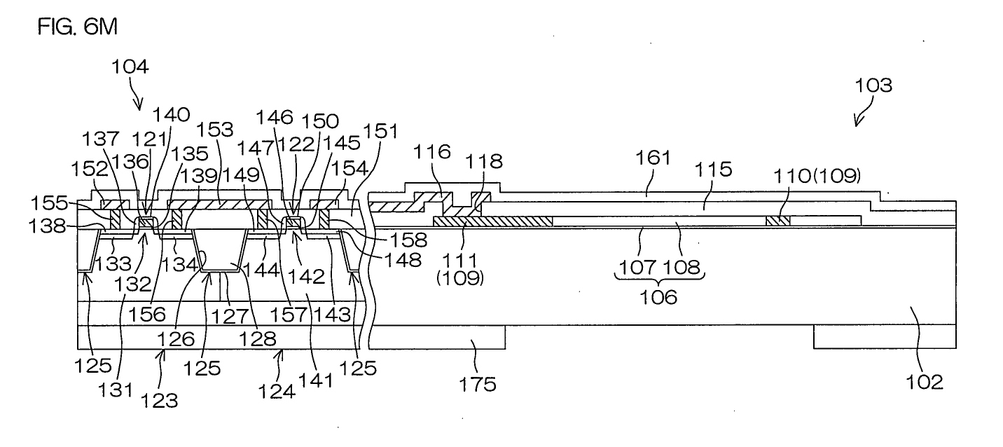

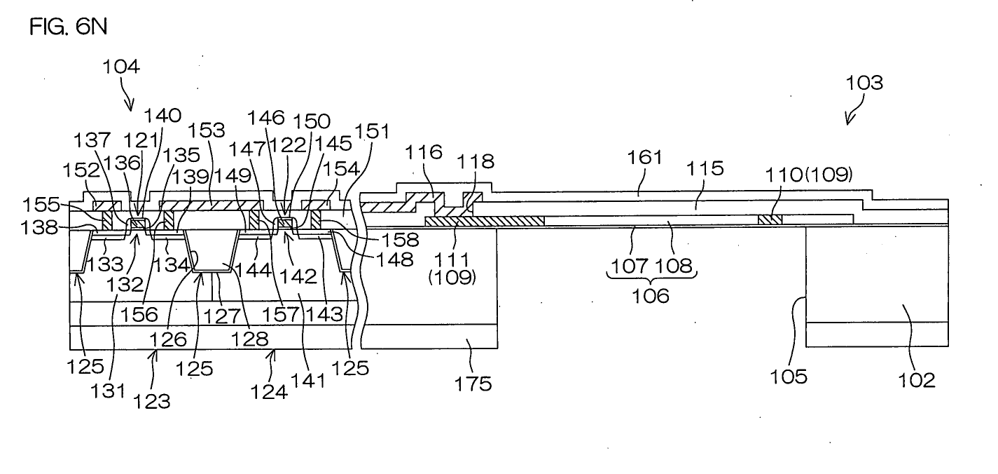

FIGS. 6A to 6N are schematic sectional views showing the steps of a pressure sensor production process in sequence. In FIGS. 6A to 6N, only electrically conductive portions are hatched, and the other portions are not hatched.

In the process for producing the pressure sensor 101, as shown in FIG. 6A, a device isolation portion 125 is first formed in a surface portion of a silicon substrate 102 by a known STI (shallow Trench Isolation) technique. Then, a P-type impurity (e.g., B (boron)) and an N-type impurity (e.g., P (phosphorus)) are implanted into an NMOS region 123 and a PMOS region 124, respectively, by an ion implantation method to form a P-type well 131 and an N-type well 141. Thereafter, an oxide film 171 of SiO₂ is formed over the entire front surface of the silicon substrate 102 by a thermal oxidation method or a CVD method.

Then, as shown in FIG. 6B, a polysilicon deposition layer 172 is formed on the oxide film 171 by a CVD method.

Thereafter, as shown in FIG. 6C, a resist pattern 173 is formed on the deposition layer 172 by photolithography. The resist pattern 173 is configured such as to expose only portions of the deposition layer 172 to be formed with a strain gage 109 and gate electrodes 136, 146 and cover the other portions of the deposition layer 172.

After the formation of the resist pattern 173, a P-type impurity is implanted into the deposition layer 172 by using the resist pattern 173 as a mask. Thus, as shown in FIG. 6D, the strain gage 109 and the gate electrodes 136, 146 are formed. After the implantation of the P-type impurity, the resist pattern 173 is removed.

Thereafter, as shown in FIG. 6E, another resist pattern 174 is formed on the deposition layer 172 by photolithography. The resist pattern 174 is configured such as to cover the gate electrodes 136, 146 and cover a portion of the deposition layer 172 later serving as a polysilicon layer 108 and to expose the other portions of the deposition layer 172.

Then, the deposition layer 172 is etched to be patterned by using the resist pattern 174 as a mask. Thus, as shown in FIG. 6F, the gate electrodes 136, 146 are separated from each other, and the polysilicon layer 108 is formed as having the strain gage 109. After the patterning of the deposition layer 172, the resist pattern 174 is removed. Then, an N-type impurity is implanted into a surface portion of the P-type well 131 by an ion implantation method as indicated by reference characters 138N, 139N. Further, a P-type impurity is implanted into a surface portion of the N-type well 141 by an ion implantation method as indicated by reference characters 148P, 149P.

In turn, as shown in FIG. 6G, the oxide film 171 is selectively etched away by using the polysilicon layer 108 and the gate electrodes 136, 146 as a mask. Thus, an oxide film 107 and gate insulating films 135, 145 are formed on the silicon substrate 102.

Subsequently, SiN is deposited over the silicon substrate 102 by a CVD method. Then, the resulting SiN deposition layer is etched back, whereby the sidewalls 137, 147 are formed.

After the formation of the sidewalls 137, 147, as shown in FIG. 6H, an N-type impurity is implanted into the surface portion of the P-type well 131 to a greater depth than the previously implanted N-type impurity by an ion implantation method. Thus, a source region 133 and a drain region 134 are formed. A P-type impurity is implanted into the surface portion of the N-type well 141 to a greater depth than the previously implanted P-type impurity by an ion implantation method. Thus, a source region 143 and a drain region 144 are formed. Thereafter, silicide layers 138, 139, 140, 148, 149, 150 are formed.

Subsequently, as shown in FIG. 6I, interlevel insulating films 115, 151 are formed by a CVD method.

After the formation of the interlevel insulating films 115, 151, through-holes are formed in the interlevel insulating film 151 in opposed relation to the source regions 133, 143 and the drain regions 134, 144 as extending thicknesswise through the interlevel insulating film 151 by photolithography and etching. Then, W is fed into the respective through-holes to completely fill the through-holes by a CVD method.

Thus, as shown in FIG. 6J, contact plugs 155 to 158 are formed. Further, a through-hole 118 through which an extension portion 111 (see FIG. 4) is partly exposed and a through-hole (not shown) through which an extension portion 112 (see FIG. 4) is partly exposed are formed in the interlevel insulating film 115 by photolithography and etching.

Thereafter, an Al film is formed on the interlevel insulating films 115, 151 by a sputtering method. Then, the Al film is patterned by photolithography and etching, whereby interconnections 116, 117 (see FIG. 4), 152, 153, 154 are formed as shown in FIG. 6K.

Thereafter, as shown in FIG. 6L, a surface protecting film 161 is formed on the interlevel insulating films 115, 151 by a CVD method.

After the formation of the surface protecting film 161, as shown in FIG. 6M, a resist pattern 175 is formed on a rear surface of the silicon substrate 102 by photolithography. The resist pattern 175 is configured such as to expose a portion of the silicon substrate 102 to be formed with an opening 105 and cover the other portion of the silicon substrate 102.

Then, as shown in FIG. 6N, the opening 105 is formed in the silicon substrate 102 by etching the silicon substrate 102 with the use of the resist pattern 175 as a mask. At this time, the oxide film 107 functions as an etching stopper to prevent the etching of the polysilicon layer 108. Thereafter, the resist pattern 175 is removed, and a glass plate 162 is bonded to the rear surface of the silicon substrate 102 by an anodic bonding method. Thus, the pressure sensor 101 shown in FIG. 5 is produced.

As described above, the diaphragm 106 of the pressure sensor 101 includes the polysilicon layer 108. The strain gage 109 is formed of the doped polysilicon provided by selectively doping the polysilicon layer 108 with the conductivity-imparting impurity. When a pressure is applied to the diaphragm 106, the polysilicon layer 108 is strain-deformed, and the electrical resistance of the strain gage 109 is changed due to the strain deformation. Based on the change in electrical resistance, the level of the pressure applied to the diaphragm 106 (polysilicon layer 108) is detected.

The pressure sensor 101 can be produced by employing the less expensive silicon substrate 102, obviating the need for an SOI substrate which is much more expensive than the silicon substrate. This makes it possible to produce the pressure sensor 101 at lower costs than the prior art pressure sensor.

The strain gage 109 has a C-shape extending along the periphery of the opening 105 inside the opening 105 as seen in plan. Thus, a change in the electrical resistance of the strain gage 109 can be properly detected in response to deformation of the polysilicon layer 108 in any of various directions. This improves the sensitivity of the pressure sensor 101.

Further, the N-channel MOSFET 121, the P-channel MOSFET 122 and other semiconductor elements can be formed by utilizing the silicon substrate 102 which supports the diaphragm 106. In the pressure sensor 101, the interconnections 152, 153, 154, which are provided on the silicon substrate 102 with the intervention of the interlevel insulating film 151, are connected to the N-channel MOSFET 121 and the P-channel MOSFET 122 via the contact plugs 155 to 158, whereby the integrated circuit is provided. The integrated circuit serves as a signal processing circuit which processes a signal from a pressure sensor portion (MEMS sensor portion) including the diaphragm 106 and the strain gage 109. The integrated circuit is preferably provided in a portion of the silicon substrate 102 around the diaphragm 106. Thus, the integrated circuit and the pressure sensor portion can be integrated into a single chip.

In the pressure sensor 101, the gate electrode 136 of the N-channel MOSFET 121 and the gate electrode 146 of the P-channel MOSFET 122 are provided at the same level as the polysilicon layer 108. This makes it possible to form the gate electrodes 136, 146 and the polysilicon layer 108 in the same step, thereby simplifying the production process for the pressure sensor 101.

While the pressure sensor 101 has thus been described by way of the embodiment, the present invention may be embodied in other ways.

Although the polysilicon layer 108 is selectively formed in the sensor region 103 of the pressure sensor 101 by patterning the polysilicon deposition layer 172, the polysilicon layer 108 may be formed in the entire sensor region 103 without etching the deposition layer 172 in the sensor region 103.

In the pressure sensor 101, the silicon substrate 102 is employed as an example of the semiconductor substrate, but a substrate of a semiconductor material other than silicon, such as an SiC (silicon carbide) substrate, may be used instead of the silicon substrate 102.

Further, the pressure sensor may include a piezoelectric element provided instead of the strain gage 109 on the diaphragm 106.

While the silicon microphone 1 and the pressure sensor 101 have thus been described as examples of the MEMS sensor in detail, it should be understood that these are merely illustrative of the technical principles of the present invention but not limitative of the invention. The spirit and scope of the present invention are to be limited only by the appended claims.

This application corresponds to Japanese Patent Application Nos. 2009-161038 and 2009-161039 filed in the Japanese Patent Office on Jul. 7, 2009 and Japanese Patent Application No. 2010-120392 filed in the Japanese Patent Office on May 26, 2010, the disclosure of which is incorporated herein by reference in entirety.

What is claimed is:

1. An MEMS sensor comprising:
a semiconductor substrate having an opening extending therethrough;
a vibration diaphragm opposed to the opening in an opposing direction and capable of vibrating in the opposing direction; and
one of a piezoelectric element and a strain gage provided in association with the vibration diaphragm.

2. The MEMS sensor according to claim 1,
wherein the vibration diaphragm is supported by a portion of the semiconductor substrate around the opening,
wherein the piezoelectric element is provided on the vibration diaphragm.

3. The MEMS sensor according to claim 2,
wherein the vibration diaphragm has an air vent extending therethrough as communicating with the opening.

4. The MEMS sensor according to claim 1, which is a silicon microphone.

5. The MEMS sensor according to claim 1,
wherein the vibration diaphragm includes a polysilicon layer which closes the opening from one side of the semiconductor substrate,
wherein the strain gage is defined by a portion of the polysilicon layer selectively doped with a conductivity-imparting impurity, and has an electrical resistance that is changed by strain deformation of the polysilicon layer.

6. The MEMS sensor according to claim 5,
wherein the strain gage has an impurity concentration of 1×10¹⁹/cm³ to 1×10²¹/cm³.

7. The MEMS sensor according to claim 5,
wherein the strain gage has a C-shape extending along a periphery of the opening inside the opening as seen in plan.

8. The MEMS sensor according to claim 1, which is a pressure sensor.

9. The MEMS sensor according to claim 1, further comprising:
a semiconductor element provided in the semiconductor substrate; and
an interconnection connected to the semiconductor element.

10. The MEMS sensor according to claim 9,
wherein the semiconductor element and the interconnection are provided around the vibration diaphragm in the semiconductor substrate.

11. The MEMS sensor according to claim 9,
wherein the semiconductor element defines apart of a signal processing circuit which processes a signal from an MEMS sensor portion including the vibration diaphragm, and the one of the piezoelectric element and the strain gage.

12. The MEMS sensor according to claim 9,
wherein an MEMS sensor portion including the vibration diaphragm, and the one of the piezoelectric element and the strain gage, and the semiconductor element are integrated into a single chip.

13. A silicon microphone comprising:
a semiconductor substrate having an opening extending therethrough;
a vibration diaphragm opposed to the opening in an opposing direction and supported by a portion of the semiconductor substrate around the opening, the vibration diaphragm being capable of vibrating in the opposing direction; and
a piezoelectric element provided on the vibration diaphragm.

14. The silicon microphone according to claim 13, further comprising:
a semiconductor element provided in the semiconductor substrate; and
an interconnection connected to the semiconductor element.

15. The silicon microphone according to claim 13,
wherein the vibration diaphragm has an air vent extending therethrough as communicating with the opening.

16. A pressure sensor comprising:
a semiconductor substrate having an opening extending therethrough;
a polysilicon layer which closes the opening from one side of the semiconductor substrate, and has a portion opposed to the opening in an opposing direction and capable of vibrating in the opposing direction; and
a strain gage defined by a portion of the polysilicon layer selectively doped with a conductivity-imparting impurity, and having an electrical resistance that is changed by strain deformation of the polysilicon layer.

17. The pressure sensor according to claim 16,
wherein the strain gage has a C-shape extending along a periphery of the opening inside the opening as seen in plan.

18. The pressure sensor according to claim 16, further comprising:
a semiconductor element provided in the semiconductor substrate; and
an interconnection connected to the semiconductor element.

19. The pressure sensor according to claim 16,
wherein the strain gage has an impurity concentration of 1×10¹⁹/cm³ to 1×10²¹/cm³.
